(19) United States
(12) Patent Application Publication
(10) Pub. No.: US 2018/0175273 A1
(43) Pub. Date: Jun. 21, 2018

(54) TERAHERTZ-BAND ELECTROMAGNETIC WAVE OSCILLATION ELEMENT AND TERAHERTZBAND ELECTROMAGNETIC WAVE OSCILLATION DEVICE

(71) Applicant: UNIVERSITY OF CENTRAL FLORIDA RESEARCH FOUNDATION INCORPORATED, Orlando, FL (US)

(72) Inventors: Takanari KASHIWAGI, Ibaraki (JP); Kazuo KADOWAKI, Ibaraki (JP); Hidetoshi MINAMI, Ibaraki (JP); Richard Andrew KLEMM, Orlando, FL (US)

(73) Assignee: UNIVERSITY OF CENTRAL FLORIDA RESEARCH FOUNDATION, INC., Orlando, FL (US)

(21) Appl. No.: 15/737,086

(22) PCT Filed: Jun. 17, 2016
(86) PCT No.: PCT/JP2016/068107

§ 371 Date: Dec. 15, 2017

(30) Foreign Application Priority Data
Jun. 17, 2015 (JP) 2015-122057

(51) Int. Cl. H01L 39/22; H01L 39/02; H01L 39/04; H03B 15/00

(52) U.S. Cl. CPC H01L 39/223; H03B 15/003; H01L 39/045; H01L 39/025

(57) ABSTRACT

Provided is a terahertz-band electromagnetic wave oscillation element that includes an independent terahertz wave oscillation unit for oscillating terahertz-band electromagnetic waves. The terahertz wave oscillation unit consists of a discoid superconductor having a multilayered Josephson junction that enables oscillation of the terahertz-band electromagnetic waves by coordinated vibration of a plurality of Josephson junctions using an AC Josephson effect, the superconductor being circular in a cross section parallel to a lamination plane of the multilayered Josephson junction.

### TECHNICAL FIELD

The present invention relates to a terahertz-band electromagnetic wave oscillation element and a terahertz-band electromagnetic wave oscillation device.

Priority is claimed on Japanese Patent Application No. 2015-122057, filed on Jun. 17, 2015, the content of which is incorporated herein by reference.

### BACKGROUND ART

Terahertz (THz) waves are electromagnetic waves having a wavelength of an intermediate region between a radio wave and light (infrared). Frequencies of the terahertz waves have no clear definition, but are said to be 300 GHz to 10 THz (a wavelength of 30 μm to 1 mm). This frequency band is nearly equal to a frequency such as orientation or spinning of a molecule, vibration of a high molecule, vibration between molecules bonded by hydrogen bonding, crystal lattice vibration, or the like. For this reason, the frequency band can be used for the identification of organic substances, high-molecular compounds, enzymes, proteins, and biomaterials. The frequency band can be applied to the identification of these materials as well as very broad fields such as non-destructive inspection, security, medical diagnosis, weather observation, environmental monitoring, astronomy, high-speed high-capacity communication, and so on, and attracts an attention.

As means for oscillating the terahertz waves, for example, a quantum cascade laser (QCL), a resonant tunneling diode (RTD), an oscillator using Josephson coupling between a superconducting layer and an insulating layer in a superconductor, etc. are known.

The QCL is oscillated using optical transition between energy levels formed in a semiconductor quantum well. When an energy difference formed in the semiconductor quantum well is small, transition caused by heat energy occurs, and proper driving is difficult in a temperature region lower than or equal to the boiling point of nitrogen. The RTD uses the motion of conduction electrons in a semiconductor. For this reason, there is a need to properly control driving of the conduction electrons. When a specific frequency spectrum is oscillated, it is difficult to properly perform the driving of the electrons.

Meanwhile, attention has recently been focused on an oscillator using an intrinsic Josephson junction which a high-temperature superconductor has (e.g., Patent Literatures 1 and 2, and Non-Patent Literature 1). This oscillator emits terahertz waves using Josephson plasma associated with an AC Josephson effect of the superconductor. A natural frequency which a geometric structure has and the Josephson plasma are made to resonate, and thereby this oscillator emits the terahertz wave having a strong peak intensity.

### CITATION LIST

### Patent Literature

### Patent Literature 1

Japanese Unexamined Patent Application, First Publication No. 2009-43787

### Patent Literature 2

Japanese Unexamined Patent Application, First Publication No. 2005-251863

### Non-Patent Literature

### Non-Patent Literature 1

Tsujimoto et al. Phys. Rev. Lett. 105, 037005(2010)

### SUMMARY OF INVENTION

### Technical Problem

A terahertz-band electromagnetic wave oscillation element using the intrinsic Josephson junction which the high-temperature superconductor has is said to be able to realize oscillation of about 15 THz in principle. However, the reality is that it is not reported that the oscillation of the terahertz waves of the high frequency region can be realized. At present, as an example reported as the terahertz-band electromagnetic wave oscillation element using the intrinsic Josephson junction which the high-temperature superconductor has, an example in which a terahertz wave of 1.6 THz is observed is a maximum example.

The oscillated terahertz wave is generally proportional to the voltage applied to the superconductor. For this reason, if the voltage applied to the superconductor is increased, the terahertz wave having a high frequency can be possibly oscillated in principle. However, in the actual element, when the voltage applied to the superconductor is increased, the superconductor generates heat. When the superconductor generates heat, an insulation property of the insulating layer of the superconductor having a laminated structure of the superconducting layer and the insulating layer is deteriorated. According to circumstances, a high temperature part called a partial hot spot is formed in the superconductor. This part deteriorates a behavior as short resistance and the insulation property of the insulating layer. For this reason, the voltage applied to a single crystal of the superconductor cannot be simply raised, a terahertz-band electromagnetic wave oscillation element using a superconductor that can oscillate a terahertz wave having a frequency of 1.6 THz or more is not reported.

To increase a range of use for the terahertz-band electromagnetic wave oscillation element and a terahertz-band electromagnetic wave oscillation device using the superconductor, a terahertz-band electromagnetic wave oscillation element and a terahertz-band electromagnetic wave oscillation device using the superconductor that can oscillate the terahertz waves having a high frequency are ardently required.

The present invention was made in view of the above problems, and an object thereof is to provide a terahertz-band electromagnetic wave oscillation element and a terahertz-band electromagnetic wave oscillation device capable of efficiently exhausting generated heat.

### Solution to Problem

As a result of earnest investigation, the inventors of the present invention found that a voltage is applied to an independent superconductor that has a predetermined shape and does not have a substrate formed of a superconductor at a lower portion of a structure thereof, and thereby a terahertz wave having a high frequency is oscillated.

That is, the present invention provides the following means to resolve the above problems.

(1) A terahertz-band electromagnetic wave oscillation element according to an aspect of the present invention includes an independent terahertz wave oscillation unit configured to oscillate terahertz-band electromagnetic waves. The terahertz wave oscillation unit consists of a discoid superconductor having a multilayered Josephson junction that enables oscillation of the terahertz-band electromagnetic waves by coordinated vibration of a plurality of Josephson junctions using an AC Josephson effect, the superconductor being circular in a cross section parallel to a lamination plane of the multilayered Josephson junction.

(2) The terahertz-band electromagnetic wave oscillation element described in (1) above may further include electrodes connected to opposite end faces of the superconductor.

(3) The terahertz-band electromagnetic wave oscillation element described in (2) above may further include a substrate configured to support any of the electrodes. A thermal conductivity of the substrate may be higher than that of the superconductor.

(4) In the terahertz-band electromagnetic wave oscillation element described in (1) above, the substrate may be any one of sapphire, diamond or copper.

(5) In the terahertz-band electromagnetic wave oscillation element described in any one of (1) to (4) above, a plurality of superconductors may be arranged between the electrodes.

(6) A terahertz-band electromagnetic wave oscillation device according to an aspect of the present invention includes: the terahertz-band electromagnetic wave oscillation element described in any one of (1) to (5) above; and a voltage applying means configured to apply a voltage to the electrodes.

### Advantageous Effects of Invention

The terahertz-band electromagnetic wave oscillation element and the terahertz-band electromagnetic wave oscillation device according to the aspect of the present invention can oscillate a terahertz wave having a frequency of 2 THz or more.

### BRIEF DESCRIPTION OF DRAWINGS

FIG. 1 is a schematic perspective view of a terahertz-band electromagnetic wave oscillation element according to an embodiment of the present embodiment.

FIG. 2 is a view schematically illustrating a crystal structure of a single crystal of a superconductor.

FIG. 3 is an example of a conventional terahertz-band electromagnetic wave oscillation element, and is a schematic perspective view of the terahertz-band electromagnetic wave oscillation element described in Non-Patent Literature 1.

FIG. 4 is a schematic perspective view of a terahertz wave oscillation element according to another embodiment of the present invention, and schematically illustrates a structure in which a plurality of superconductors are arranged.

FIG. 5 is a schematic perspective view of a terahertz wave oscillation element according to an embodiment of the present invention, and is a schematic sectional view of a case in which electrodes are processed in a horn antenna shape.

FIG. 6 is a schematic perspective view of a terahertz-band electromagnetic wave oscillation element according to another embodiment of the present invention.

FIG. 7 is a schematic perspective view of a terahertz-band electromagnetic wave oscillation device according to an embodiment of the present invention.

FIG. 8 illustrates oscillation spectrums of Example 1.

### DESCRIPTION OF EMBODIMENTS

Hereinafter, a terahertz-band electromagnetic wave oscillation element and a terahertz-band electromagnetic wave oscillation device will be described in detail with appropriate reference to the drawings.

The drawings used in the following description may illustrate characterized portions in a larger size for convenience so that the features can be easily understood, and dimension ratios of the components may be different from reality. Materials, dimensions, etc. exemplified in the following description are examples, and the present invention is not limited thereto, but may be implemented with appropriate modification without departing from the spirit and scope thereof.

### Terahertz-Band Electromagnetic Wave Oscillation Element

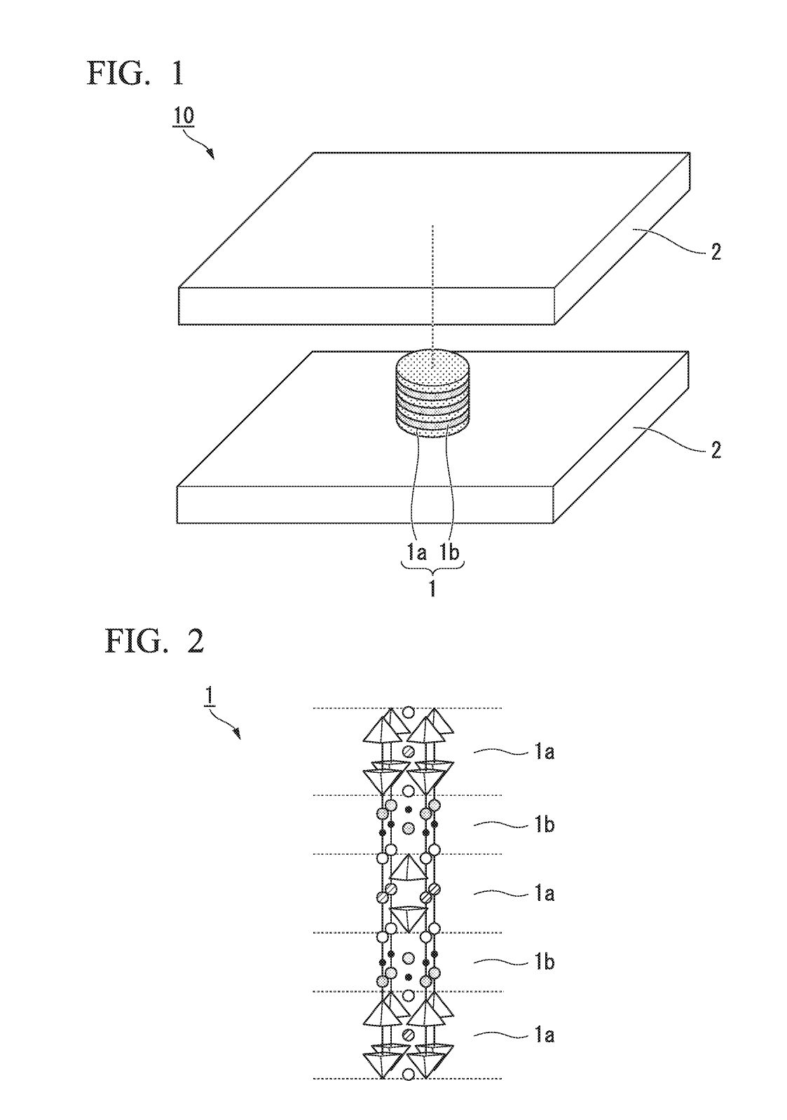

FIG. 1 is a schematic perspective view of a terahertz-band electromagnetic wave oscillation element according to the present embodiment. As illustrated in FIG. 1, a terahertz-band electromagnetic wave oscillation element 10 according to the present embodiment has a discoid superconductor 1 of which a terahertz wave oscillation unit oscillating terahertz-band electromagnetic waves is formed.

Electrodes 2 are connected to opposite ends of the superconductor 1. In FIG. 1, the electrodes 2 are illustrated as being larger than the superconductor 1, but they are not limited to this case. For example, the electrodes 2 may be point contacts. In FIG. 1, in order for the constitution of the invention to be easily understood, one of the electrodes is illustrated as being separated, but it is actually connected to an end face of the superconductor 1. A circumference of the superconductor 1 may be covered with thermal grease or the like that has high thermal conductivity.

The superconductor 1 has a laminated structure of a superconducting layer and an insulating layer. That is, the superconductor 1 has a structure in which Josephson junctions are laminated. FIG. 2 is a crystal structure of Bi₂Sr₂CaCu₂O_{8+δ} (Bi2212) that is an example of the superconductor 1. In FIG. 2, a trigonal pyramid is composed of Cu and O, a white circle indicates Sr, a black circle indicates oxygen, a circle with an oblique line indicates Ca, and a circle with a point-like pattern indicates Bi. In the case of FIG. 2, a CuO₂ layer serves as the superconducting layer 1a and a Bi₂O₂ layer serves as the insulating layer 1b. That is, the superconductor 1 has a structure in which the superconducting layer 1a/the insulating layer 1b/the superconducting layer 1a are laminated at an atomic level.

A supercurrent flows to each superconducting layer 1a via the insulating layer 1b due to a Josephson effect. In the case of Bi2212, about 670 Josephson junctions are formed in a single crystal of 1 μm.

In FIG. 2, Bi2212 is presented as an example of the single crystal 1. However, as long as the superconductor 1 can generate an alternating current (AC) Josephson effect, the superconductor 1 is not limited to the crystal structure. For example, Bi₂Sr₂Ca₂Cu₃O_{10+δ} (Bi2223) or the like that has a different crystal structure may be used.

When a voltage is applied to the superconductor 1 in a direction perpendicular to a lamination plane of the Josephson junction, the terahertz wave is oscillated. A principle of the oscillation of the terahertz wave will be simply described below.

When the voltage is applied in a direction perpendicular to the lamination plane of the Josephson junction of the superconductor 1, the AC Josephson effect is generated. The AC Josephson effect refers to a phenomenon in which an alternating current flows when a constant voltage V_{J} is applied between two superconductors between which a very thin insulating layer is interposed.

At this time, a frequency f_{J} of the alternating current is expressed by Formula (1) below. In Formula (1), e is the elementary electric charge, and h is the Planck's constant.

f_{J}=(2e/h)V_{J} (1)

Since the elementary electric charge and the Planck's constant are constant, the frequency f_{J} of the alternating current is proportional to the applied voltage V_{J} per Josephson junction layer as shown Formula (1). In this way, a current flows into the single crystal 1, and thereby an electromagnetic wave (hereinafter may be referred to as “non-resonant terahertz wave”) is generated. This electromagnetic wave is a terahertz wave, and is emitted from the terahertz wave oscillation unit consisting of the superconductor 1 to the outside.

Here, an intensity of the oscillated terahertz wave is not very strong. The terahertz wave having a strong intensity is obtained by resonating with a natural frequency f_{c} generated by a geometric structure of the superconductor 1.

The natural frequency f_{c} is a frequency that is affected by a shape and size of a material. If a certain material has a closed region, a standing wave based on boundary conditions is formed in the material. A frequency of this standing wave is the natural frequency f_{c}.

For example, as illustrated in FIG. 1, when the superconductor 1 has a disc shape, the standing wave is formed in the superconductor 1. In the case of the disc shape, the natural frequency f_{c} is expressed below.

f_{c}=χ₁₁c₀/2πna (2)

Here, in the case of a fundamental frequency, χ₁₁ is 1.841, c₀ is the velocity of light in a vacuum, n is the refractive index, and a is the radius of the disc.

When this natural frequency f_{c} is identical to the frequency f_{J} of an oscillating current associated with the AC Josephson effect, the oscillating current flows between the laminated Josephson junctions with phases aligned (coherent), and resonance is generated. As a result, a terahertz wave (which may be referred to hereinafter as “resonant terahertz wave”) having a strong intensity peak is emitted from the terahertz wave oscillation unit consisting of the superconductor 1 to the outside.

The terahertz wave oscillation unit consists of the discoid superconductor 1. In a conventional terahertz-band electromagnetic wave oscillation element, in addition to the discoid superconductor, a superconductor on a substrate is generally provided at a lower side of the discoid superconductor, and this point is different.

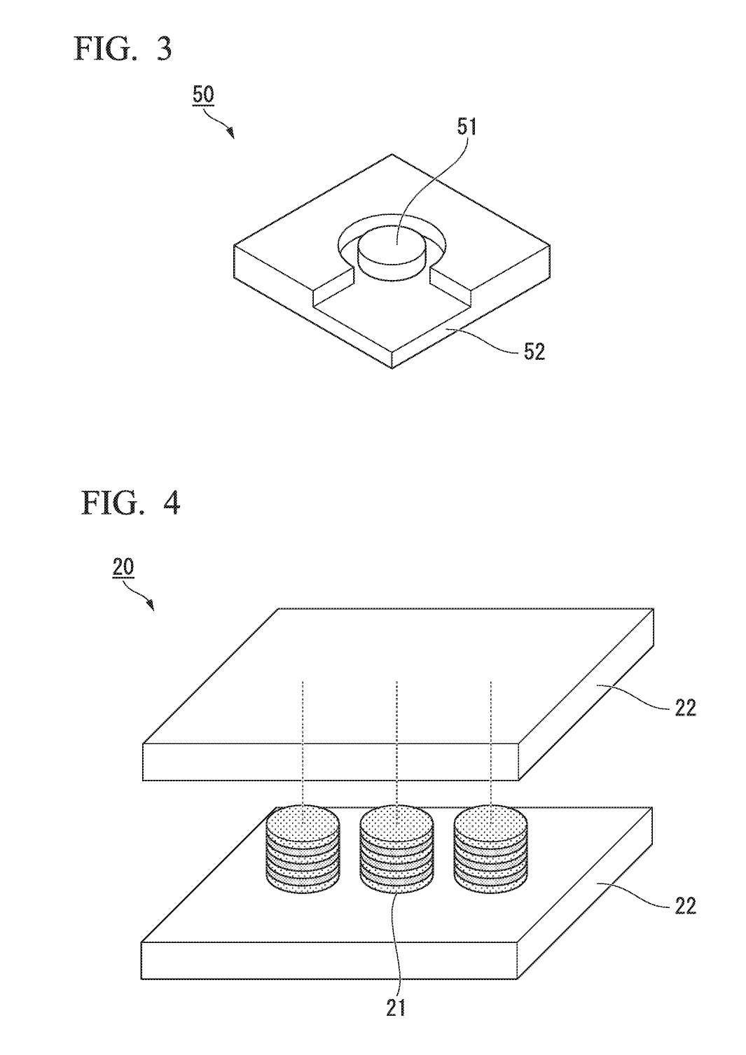

FIG. 3 is an example of the conventional terahertz-band electromagnetic wave oscillation element, and is a schematic perspective view of the terahertz-band electromagnetic wave oscillation element described in Non-Patent Literature 1. As illustrated in FIG. 3, the conventional terahertz-band electromagnetic wave oscillation element 50 is formed by processing a large superconductive single crystal to cut it with a focused ion beam (FIB). That is, a portion formed at a lower side of a mesa part 51 by processing functions as a substrate 52. In other words, the mesa part 51 and the substrate 52 provided at the lower side of the mesa part 51 are formed of the same superconductor, and are integrated.

When a voltage is applied to the conventional terahertz-band electromagnetic wave oscillation element 50, an alternating current is generated at both the mesa part 51 and the substrate 52 formed of a single crystal of the same superconductor. That is, the terahertz wave is generated by the mesa part 51 and the substrate 52. In reality, since a main factor determining the natural frequency f_{c} is the mesa part 51, the resonant terahertz wave is oscillated from the mesa part 51. However, the mesa part 51 is integrated with the substrate 52 and is not independent, and a boundary thereof is not clear.

In contrast, the terahertz wave oscillation unit according to the present embodiment consists of the discoid superconductor 1.

The electrodes 2 are connected to the opposite ends of the superconductor 1. However, the superconductor 1 and the electrodes 2 are different materials. In this way, the terahertz wave oscillation unit consists of the discoid superconductor 1, which may be expressed herein as being “independent”.

When the superconductor 1 is present independently, there are two advantages.

First, the first advantage is that a value of the natural frequency f_{c} becomes clear. Like the terahertz-band electromagnetic wave oscillation element 50, when the mesa part 51 and the substrate 52 are integrated, a boundary between the mesa part 51 and the substrate 52 becomes unclear. For this reason, a waveform of the standing wave formed in a closed space also becomes unclear. As a result, a peak of a wavelength of the natural frequency f_{c} also becomes broad. In contrast, when the superconductor 1 is present independently, the superconductor 1 forms a clear closed space, and thus the value of the natural frequency f_{c} becomes clear. Therefore, the terahertz wave having a higher intensity is easily oscillated.

The second advantage is that a temperature of the superconductor 1 is inhibited from rising. As shown in Formula (1), to oscillate a terahertz wave having a high frequency region, there is a need to increase the voltage applied to the superconductor 1. However, if the voltage applied to the superconductor 1 is increased, the superconductor 1 generates heat so much. When the superconductor generates heat, an insulation property of the insulating layer of the superconductor having the laminated structure of the superconducting layer and the insulating layer is deteriorated. The AC Josephson effect is the phenomenon in which, when the constant voltage is applied between the two superconductors between which the very thin insulating layer is interposed, the alternating current flows. For this reason, when the insulation property of the insulating layer is deteriorated, a desired AC Josephson effect cannot be obtained, and the terahertz wave cannot be oscillated.

Like the terahertz-band electromagnetic wave oscillation element 50, when the mesa part 51 and the substrate 52 are integrated, the substrate 52 obstructs exhaust heat. Since the substrate 52 is formed of the superconductor, thermal conductivity is very poor. In contrast, when the superconductor 1 in the present embodiment is present independently, heat can be exhausted in all directions around the superconductor 1, and the temperature of the superconductor 1 can be inhibited from rising. As a result, a high voltage can be applied, and the terahertz wave having a high frequency region can be oscillated as shown in Formula (1).

Next, a shape of the superconductor 1 will be described.

The superconductor 1 is in a disc shape. “Disc shape” as used herein means that a cross section parallel to the lamination plane of the multilayered Josephson junction has a circular shape, and may include a column. The superconductor 1 has the disc shape and is present independently, and thereby a terahertz wave of 2 THz or more can be oscillated.

The terahertz wave of 2 THz or more is checked only when the shape of the superconductor 1 is formed in the disc shape. The reason for this is not clear, and at this moment, the terahertz wave of 2 THz or more cannot be checked when the shape of the superconductor 1 is formed in a cuboid shape in which the cross section parallel to the lamination plane of the multilayered Josephson junction has a rectangular shape.

When the terahertz-band electromagnetic wave oscillation element having the substrate at the lower side as illustrated in FIG. 3 is used, a shape of the mesa part thereof is changed from a cuboid shape to a disc shape, and thereby the wavelength of the oscillated terahertz wave does not become a high frequency.

That is, the superconductor 1 has the disc shape and is present independently, and thereby the terahertz wave of 2 THz or more can be oscillated. This was discovered first by the inventors of the present invention as a result of various studies.

A height of the superconductor 1 preferably ranges from 1 μm to 10 μm. When the height of the superconductor 1 is set to this range, the terahertz wave having a high intensity can be oscillated while the temperature of the superconductor 1 is prevented from becoming too high. The height of the superconductor 1 refers to a thickness of the superconductor 1 in a direction perpendicular to the lamination plane of the multilayered Josephson junction.

The height of the superconductor 1 is calculated in terms of the number N of Josephson junctions formed in the superconductor 1.

For example, when the height of the superconductor 1 is defined as h, and a length of a c-axis of the crystal of the superconductor is defined as the following relation is established.

N=h/(h/2) (3)

If the number N of Josephson junctions is increased, the oscillated terahertz wave has a higher intensity.

If the height of the superconductor 1 is sufficient, the terahertz wave having a higher intensity can be oscillated. When the height of the superconductor 1 is less than or equal to 1 μm, the superconductor 1 is too thin to handle.

The voltage V_{J} shown in Formula (1) is consistently the applied voltage per Josephson junction layer. For this reason, if the number of Josephson junctions is N, a voltage V actually applied to the entire superconductor 1 becomes

V=N×V_{J} (4)

That is, when the height of the superconductor 1 is increased, the number N of Josephson junctions also increases, and the voltage V applied to the entire superconductor 1 becomes unusually high. As a result, the superconductor 1 easily generates heat. For example, from the viewpoint of avoiding the deterioration of the insulation property of the insulating layer 1b in long-term use, the height of the superconductor 1 is preferably less than or equal to 10 μm.

A diameter of the discoid superconductor 1 can be properly designed. Here, the diameter of the discoid superconductor 1 refers to a diameter in the cross section parallel to the lamination plane of the multilayered Josephson junction. When the diameter of the cross section varies, the diameter refers to an average value of the varying diameters.

As shown in Formula (2), the natural frequency f_{c} when the superconductor 1 has a disc shape is affected by a diameter of the disc. It is unclear whether the terahertz wave having a frequency of 2 THz or more from the disc-shaped and independent superconductor 1 is the non-resonant terahertz wave or the resonant terahertz wave. For this reason, the diameter of the discoid superconductor 1 is not necessarily the value obtained from Formula (2). However, when the diameter of the discoid superconductor 1 is set to this range, the terahertz wave easily resonates with the frequency f_{J} of the alternating current in the superconductor 1, and the terahertz wave having a higher intensity is easily obtained.

In the discoid superconductor 1, widths of upper and lower bottom portions thereof are preferably identical to each other. The constitution in which the widths of the upper and lower bottom portions of the superconductor 1 are identical to each other means that end faces (sides) of the superconductor 1 are perpendicular to the substrate. For this reason, the standing wave formed in the superconductor 1 only becomes a specified frequency. When this constant natural frequency f_{c} and the frequency f_{J} of the oscillating current associated with the AC Josephson effect are identical to each other, a more monochromatic terahertz wave can be obtained. Since the laminated Josephson junctions resonate and the terahertz wave is oscillated, if the end faces of the superconductor are perpendicular to the substrate, the high intensity is shown at a specified wavelength, and the more monochromatic terahertz wave can be obtained.

There need not be only one superconductor. For example, FIG. 4 is a schematic perspective view of a terahertz wave oscillation element according to another embodiment of the present invention. In the terahertz wave oscillation element 20 illustrated in FIG. 4, a plurality of superconductors 21 are arranged between two electrodes 22. Here, the superconductors 21 are arranged by setting a direction in which a voltage is applied to be the same direction.

When the number of superconductors 21 is two or more, the number of oscillation sources of the terahertz wave becomes two or more, and thus an oscillation intensity of the terahertz wave can be increased.

It is more preferable that the superconductors 21 be regularly juxtaposed at predetermined intervals. When the superconductors 21 are regularly juxtaposed at predetermined intervals, the plurality of superconductors 21 can be operated in a coordinated fashion, and the oscillation intensity of the terahertz wave can be dramatically enhanced.

The oscillation intensity obtained at this time is affected by a coordinated operation of the plurality of superconductors 21. For this reason, the oscillation intensity is proportional to a square of the number of superconductors 21. Since the Josephson junctions laminated in one of the superconductors 21 are also operate in coordination in the same way, the oscillation intensity is proportional to a square of the laminated number. That is, when N single crystals formed by laminating M layers are juxtaposed at predetermined intervals, an oscillation intensity of M²×N² can be realized, and oscillation of a very strong terahertz wave can be realized. The predetermined intervals are intervals at which the superconductors 21 resonate, and are calculated from an oscillated frequency.

This multiple arrangement can also be realized in principle in the conventional terahertz-band electromagnetic wave oscillation element 50. However, in the conventional terahertz-band electromagnetic wave oscillation element 50, a problem that a rise in temperature caused by heat generation from the superconductors is unusually great, a problem that thermal reciprocal interference by the superconductors occurs, a problem that the voltage applied to each superconductor is reduced, etc. are found. For this reason, it is difficult to actually realize the multiple arrangement. In contrast, when the superconductor 21 is independently used, integration density of the superconductors 21 can be increased. That is, the oscillation of the terahertz wave caused by the coordinated operation can be performed at a higher intensity.

In FIG. 4, the plurality of superconductors 21 are arranged between the two electrodes 22, but the embodiment is not limited to this case. The electrodes may be connected to each of the superconductors 21. However, from the viewpoint of simplifying an element structure, the constitution of FIG. 4 is preferred.

Returning to FIG. 1, the electrodes 2 are connected to the opposite end faces of the superconductor 1. Since the superconductor 1 is in the disc shape, the opposite end faces are two circular end faces in a top view. That is, the electrodes 2 are located in the direction perpendicular to the lamination plane of the superconductor 1 having the multilayered Josephson junction.

The electrodes 2 preferably have higher thermal conductivity than the superconductor 1. When the electrodes 2 have a certain degree of thickness, the electrodes 2 greatly contribute to the exhaust heat of the superconductor 1. For this reason, the thermal conductivity of the electrodes 2 is higher than that of the superconductor 1, and thereby the temperature of the superconductor 1 can be inhibited from becoming high. When the electrodes 2 are unusually thin, the electrodes 2 do not greatly contribute to the exhaust heat of the superconductor 1, but the electrodes suitably have higher thermal conductivity than the superconductor 1 from the viewpoint of the exhaust heat.

The electrodes 2 preferably have high electrical conductivity. As a material having high thermal conductivity and high electrical conductivity, copper (Cu), gold (Au), silver (Ag), aluminum (Al), etc. may be used.

The electrodes 2 need only be connected to the superconductor 1, and shapes thereof do not matter, and can be appropriately modified according to a mode of use. Since the superconductor 1 itself can transport electric charges by the Josephson current, if the superconductor 1 has a contact in any case, the voltage can be applied to the superconductor 1.

From the viewpoint of uniformly applying the voltage to the lamination plane of the Josephson junction, each of the electrodes 2 is preferably formed on the entire end face of the superconductor 1. Meanwhile, when the electrodes 2 are formed of a metal, the electrodes 2 fully reflect the terahertz wave. For this reason, the electrodes 2 may be formed at a part of the superconductor 1 at which they do not obstruct emission of the terahertz wave.

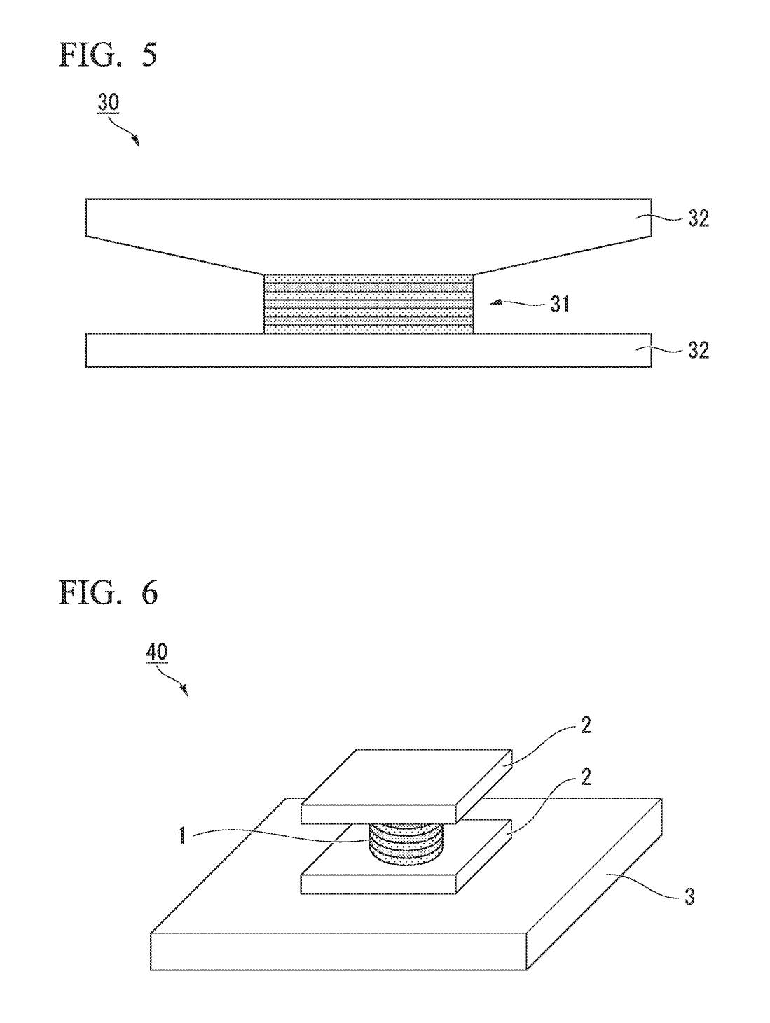

As illustrated in FIG. 5, the electrodes 32 may be processed in a horn antenna shape. FIG. 5 is a schematic sectional view of a terahertz-band electromagnetic wave oscillation element 30 in which the electrodes 32 are processed in a horn antenna shape. Here, the horn antenna shape is a structure in which a distance between the electrodes 32 widens as the electrodes 32 are farther away from the superconductor 31 at a non-junction portion at which the electrode 32 and the superconductor 31 are not joined. In other words, the horn antenna shape is a structure in which the wave from the oscillation source of the terahertz wave is formed to gradually spread. In FIG. 5, the electrode 32 of an upper side relative to the superconductor 31 is processed, but the same processing may also be performed on the electrode 32 of a lower side.

When the electrodes 32 are processed in this shape, an impedance matching characteristic between a space formed between the electrodes 32 and a free space is enhanced. For this reason, reflection of the electromagnetic wave at an open end is inhibited, and high directivity is given. That is, the efficiently generated terahertz wave can be extracted.

The structure of the electrode is not limited to the horn antenna shape. For example, the structure of the electrode may be a hemispheric lens shape in which a curved surface side thereof is joined with the superconductor. The hemispheric lens shape is not necessarily limited to a “hemisphere,” and only a curved surface in which the distance between the electrodes widens as the electrodes are farther away from the superconductor at the non-junction portion at which the electrode and the superconductor are not joined need be formed. When the electrode is processed in the hemispheric lens shape, the generated heat is efficiently exhausted, and radio waves can be efficiently light-focused. Like when the electrode is processed in the horn antenna shape, the impedance matching characteristic is enhanced.

The electrodes 2 can be joined with the superconductor 1 by a conventional well-known method such as soldering, silver pasting, or the like. When the electrodes 2 are thin, the superconductor 1 is covered with a metal film, and this metal film may be used as the electrodes.

As illustrated in FIG. 6, a substrate 3 supporting any of the electrodes 2 may be provided. FIG. 6 is a schematic perspective view of a terahertz-band electromagnetic wave oscillation element 40 according to another embodiment of the present invention. The superconductor 1 is very thin. The electrodes 2 have different thicknesses according to a mode thereof. However, when the electrodes 2 are formed by sputtering or the like, the thicknesses thereof become very thin. For this reason, when the electrodes 2 are thin, the substrate 3 supporting the electrodes 2 and the superconductor 1 is provided, and thereby a handling characteristic of the terahertz-band electromagnetic wave oscillation element 40 can be enhanced.

The substrate 3 may be processed in the horn antenna shape or the hemispheric lens shape as described above. When the substrate 3 is processed in this way, an exhaust heat characteristic of the generated heat, a light-focusing characteristic of the radio wave, and the impedance matching characteristic are enhanced.

Since the substrate 3 is connected to the superconductor 1 via the electrode 2, the substrate 3 preferably has higher thermal conductivity than the superconductor 1. Sapphire, diamond, copper, or other materials having an exhaust heat effect equivalent to or higher than those of these materials are preferably used for the substrate 3. These materials exhibit high thermal conductivity at a temperature near a boiling point of nitrogen at which the terahertz-band electromagnetic wave oscillation element is driven. For this reason, the exhaust heat of the superconductor 1 can be efficiently supported from the substrate 3 side.

As described above, when the terahertz-band electromagnetic wave oscillation element of the present invention is independently used and uses the discoid superconductor, the terahertz wave having a frequency of 2 THz or more can be oscillated.

### Terahertz-Band Electromagnetic Wave Oscillation Device

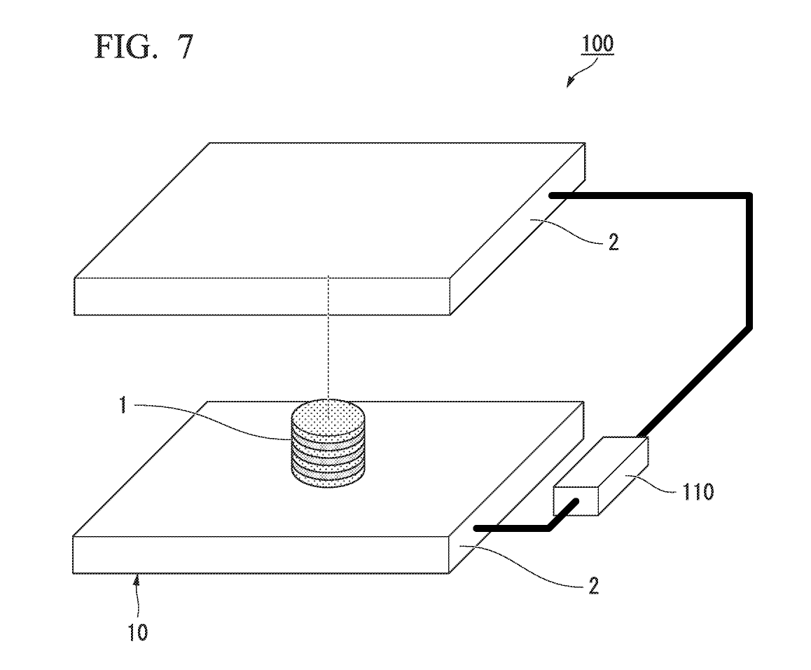

FIG. 7 is a schematic perspective view illustrating a terahertz-band electromagnetic wave oscillation device according to an embodiment of the present invention. A terahertz-band electromagnetic wave oscillation device 100 according to an embodiment of the present invention includes the above terahertz-band electromagnetic wave oscillation element 10, 20, 30, or 40, and a voltage applying means 110 that applies a voltage in a direction perpendicular to a lamination plane in a superconductor 1 having a multilayered Josephson junction. Any of the terahertz-band electromagnetic wave oscillation elements of FIG. 1, FIG. 4, FIG. 5, and FIG. 6 may be used, but the following description will be based on the terahertz-band electromagnetic wave oscillation element 10 of FIG. 1.

The voltage supplied from the voltage applying means 110 is applied to electrodes 2. The voltage applying means 110 need only be electrically connected to the electrodes 2. When bases 3 have conduction, the electrical connection between the voltage applying means 110 and the electrodes 2 may be performed via the bases 3.

When the voltage applying means 110 and the electrodes 2 are electrically connected, the voltage in the direction perpendicular to the lamination plane of the superconductor 1 can be applied. Since a laminated structure between a superconducting layer 1a and an insulating layer 1b is formed, the voltage is applied in the direction perpendicular to the lamination plane of the superconductor 1, and thereby an AC Josephson effect is generated. When a frequency of an oscillating current proportional to the applied voltage and a natural frequency of the superconductor 1 are identical to each other, resonance is generated between laminated Josephson junctions, the oscillating current flows with phases aligned (coherent), and thereby a terahertz wave is oscillated to the outside.

Preferably, the terahertz-band electromagnetic wave oscillation device 100 further includes a cooling device (not shown). The cooling device is not particularly limited as long as it can cool the terahertz-band electromagnetic wave oscillation element 10. In the present embodiment, since the superconductor 1 can be efficiently cooled, liquid nitrogen may also used as a cooling medium without using liquid helium. In comparison with the liquid helium, the liquid nitrogen is easily handled. For this reason, the cooling device can also use an inexpensive and small cooling device.

Since this terahertz-band electromagnetic wave oscillation device 100 includes the above terahertz-band electromagnetic wave oscillation element 10, the exhaust heat can be efficiently realized, and the terahertz wave of 2 THz or more can be oscillated.

The voltage applying means 110 is not particularly limited, and may be any means that enables a direct current to flow the superconductor 1.

Although preferred embodiments of the present invention have been described, the present invention is not limited to the specified embodiments, and can be variously modified and changed without departing from the spirit and scope of the present invention which are described in the claims.

### EXAMPLES

Hereinafter, effects of the above embodiments are made more apparent by examples. The embodiments are not limited to the following examples, and can be appropriately modified and carried out without departing from the spirit and scope thereof.

### Example

A discoid superconductor formed of Bi2212 having a diameter of 80 μm and a thickness of about 3.5 μm was prepared. Three different voltages were applied to this superconductor. The three voltages were set to about 5 V that is enough to oscillate a terahertz wave of a high frequency in principle. The three voltages were bias points A, B and C, and had a relation of A<B<C. Various contributions such as contact resistance were added to these voltages. All of Josephson junctions laminated in a thickness direction were not necessarily operated by the bias points. Oscillation spectrums obtained at a temperature of 15 K were measured. A spectrum when no voltage was applied was set to a background (B.G.).

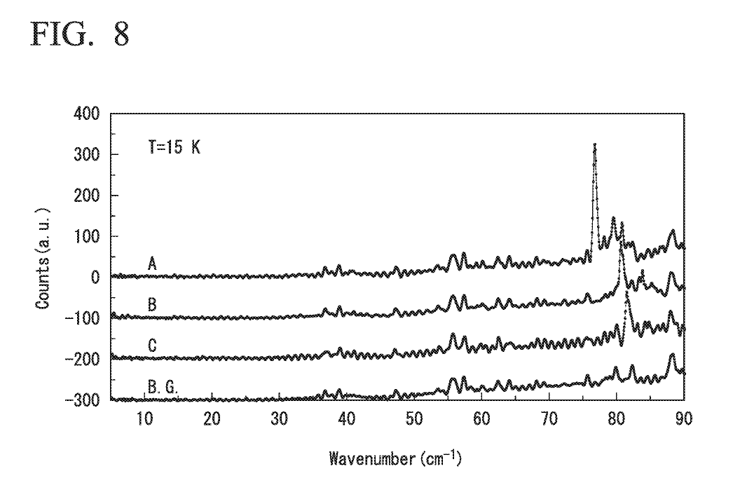

FIG. 8 illustrates the oscillation spectrums of Example 1. The longitudinal axis indicates a measured intensity, and the transverse axis indicates a wave number. The generated terahertz wave was measured using FARIS-1 available from JASCO corporation. As illustrated in FIG. 8, a signal near about 80 cm⁻¹ is confirmed. If the wave number is about 30 times, it can be calculated in terms of the oscillated frequency. That is, this signal indicates the vicinity of 2.4 THz. In this way, when a voltage was applied to a discoid and independent superconductor, it could be confirmed that the terahertz wave of 2.0 THz or more was oscillated. As the applied voltage increases, a peak position becomes larger. This shows a relation of Formula (1).

### Comparative Example

In a comparative example, a peak of an oscillation spectrum was confirmed using the terahertz-band electromagnetic wave oscillation element having the constitution of FIG. 3. A structural difference between the comparative example and the example is only whether the superconductor is formed independently.

As a result, a terahertz wave having a frequency of about 0.54 THz was confirmed. Oscillation output at this time was weak output lower than or equal to a microwatt level.

### REFERENCE SIGNS LIST

1, 21 Superconductor
1a Superconducting layer
1b Insulating layer
2, 22 Electrode
10, 20, 30, 40, 50 Terahertz-band electromagnetic wave oscillation element
51 Mesa part
52 Substrate
100 Terahertz-band electromagnetic wave oscillation device
110 Voltage applying means

What is claimed is:

1. A terahertz-band electromagnetic wave oscillation element comprising
an independent terahertz wave oscillation unit configured to oscillate terahertz-band electromagnetic waves,
wherein the terahertz wave oscillation unit consists of a discoid superconductor having a multilayered Josephson junction that enables oscillation of the terahertz-band electromagnetic waves by coordinated vibration of a plurality of Josephson junctions using an AC Josephson effect, the superconductor being circular in a cross section parallel to a lamination plane of the multilayered Josephson junction.

2. The terahertz-band electromagnetic wave oscillation element according to claim 1, further comprising electrodes connected to opposite end faces of the superconductor.

3. The terahertz-band electromagnetic wave oscillation element according to claim 2, further comprising a substrate configured to support any of the electrodes,
wherein a thermal conductivity of the substrate is higher than that of the superconductor.

4. The terahertz-band electromagnetic wave oscillation element according to claim 3, wherein the substrate is any one of sapphire, diamond or copper.

5. The terahertz-band electromagnetic wave oscillation element according to claim 2, wherein a plurality of superconductors are arranged between the electrodes.

6. A terahertz-band electromagnetic wave oscillation device comprising:
the terahertz-band electromagnetic wave oscillation element, comprising:
an independent terahertz wave oscillation unit configured to oscillate terahertz-band electromagnetic waves;
wherein the terahertz wave oscillation unit consists of a discoid superconductor having a multilayered Josephson junction that enables oscillation of the terahertz-band electromagnetic waves by coordinated vibration of a plurality of Josephson junctions using an AC Josephson effect, the superconductor being circular in a cross section parallel to a lamination plane of the multilayered Josephson junction; and
electrodes connected to opposite end faces of the superconductor; and
a voltage applying means configured to apply a voltage to the electrodes.
